(19) United States
(12) Patent Application Publication
(10) Pub. No.: US 2008/0268628 A1
(43) Pub. Date: Oct. 30, 2008

(54) N-TYPE SEMICONDUCTOR COMPONENT WITH IMPROVED DOPANT IMPLANTATION PROFILE AND METHOD OF FORMING SAME

(76) Inventors: Puneet Kohli, Austin, TX (US); Manoj Mehrotra, Plano, TX (US); Antonio Luis Pacheco Rotondaro, Dallas, TX (US); Stan Ashburn, McKinney, TX (US); Nandakumar Mahalingam, Richardson, TX (US); Amitabh Jain, Allen, TX (US)

Correspondence Address: TEXAS INSTRUMENTS INCORPORATED, P O BOX 655474, M/S 3999, DALLAS, TX, 75265, US

(21) Appl. No.: 11/739,965

(22) Filed: Apr. 25, 2007

(51) Int. Cl. H01L 21/425; H01L 29/00; H01L 21/22

(52) U.S. Cl. 438/542; 257/607; 438/511; 257/E21.473; 257/E29.001; 257/288

(57) ABSTRACT

The disclosure relates to a method of forming an n-type doped active area on a semiconductor substrate that presents an improved placement profile. The method comprises the placement of arsenic in the presence of a carbon-containing arsenic diffusion suppressant in order to reduce the diffusion of the arsenic out of the target area during heat-induced annealing. The method may additionally include the placement of an amorphizer, such as germanium, in the target area in order to reduce channeling of the arsenic ions through the crystalline lattice. The method may also include the use of arsenic in addition to another n-type dopant, e.g. phosphorus, in order to offset some of the disadvantages of a pure arsenic dopant. The disclosure also relates to a semiconductor component, e.g. an NMOS transistor, formed in accordance with the described methods.

### FIELD

The present disclosure relates generally to the fabrication of semiconductor devices, and more particularly to the process of doping areas of semiconductor devices to impart electronic activity.

### BACKGROUND

The present disclosure relates generally to the field of semiconductor fabrication. In conventional practice, semiconductor fabrication begins with the provision of a substrate wafer, comprising silicon formed in a regular, crystalline structure. A circuit pattern is devised in which regions of the substrate are intended to support NMOS and PMOS semiconductor devices. These regions are isolated from each other with the formation of electronically inert isolation trenches. Each region is then doped with a type of dopant opposite the electronic nature of the devices to be created thereupon. The formation of the semiconductor devices then occurs upon this substrate, and typically involves doping the electronically active areas of the device with the desired type of dopant. For instance, NMOS devices are often formed by implanting a p-type dopant in a region of the semiconductor, and then forming the devices by implanting an n-type dopant in order to create the electronically active regions of the NMOS device. In the case of a typical transistor, two electronically active areas are created in this manner to represent the source and drain regions of the transistor, and are bridged by forming a gate that can be operated to regulate electronic flow between the electronically active areas. The devices may then be connected through a metallization step, in which metal paths are formed to connect the electronically active areas of the devices into a fully interconnected circuit.

The disclosure more specifically relates to the process of doping a semiconductor substrate with an n-type dopant in order to form electronically active areas for these semiconductor devices. Conventional practice involves doping with an n-type dopant, which is often selected from the group IV elements, such as arsenic, phosphorus, and germanium. One method of performing this doping is by ion implantation, in which ionized particles of the compound are fired at high energy into designated areas of the semiconductor substrate. The group IV atoms enhance the n-type electronic conductivity in relation to the surrounding substrate. However, the implantation of these atoms also disrupts the lattice structure of the crystalline silicon wafer, thereby imparting an uncontrollable structural irregularity that may cause undesirable electronic or physical characteristics. This irregularity may be reduced by performing a subsequent annealing step, in which the semiconductor is exposed to high temperatures in order to re-establish the regular molecular bonds that impart a crystalline structure in the doped regions of the semiconductor.

The process described above may be used to place a dopant in a specific region that will serve as an electronically active area (referred to herein as the “target area,” both before and after doping.) It will be appreciated that in light of the trends of miniaturization and enhanced computation performance of electronic components, tight control of dopant placement is highly valued. The doping area must be controlled to form well-defined electronically active areas, and is typically delineated by the selective deposition of a photolithography layer that covers areas where doping is not desired. The doping therefore occurs only in the exposed regions, resulting in well-defined lateral borders of the electronically active areas. Also, tight controls on the depth of placement by ion implantation may improve control over the placement of dopant in the target area. The depth of ion implantation may be controlled by altering the velocity of the dopant ions fired at the semiconductor wafer, since relatively slow-moving ions will be placed at a shallower depth and within a tighter range.

However, in many doping methods, two physical characteristics may interfere with controlled placement of the dopant. First, the semiconductor substrate may form a crystalline lattice in a configuration that includes longitudinal channels. If an ion placed via ion implantation is fired at the substrate with an angle and position corresponding to a channel, it may deeply penetrate the substrate before coming to rest in a region of the lattice, resulting in undesirably deep penetration. Second, in both ion implantation and other types of dopant placement, when the substrate is heated for annealing, the target area becomes a region of high dopant concentration, and some of the dopant may diffuse out of the target area, both laterally and longitudinally, thereby disrupting the well-defined borders of the active area. Worse, the diffused dopant may connect with a neighbouring component or breach the isolation trench, causing unpredicted and undesirable electronic properties. Both of these characteristics of some doping processes disrupt the tight control of active area doping, and hence the performance and reliability of semiconductors fabricated in this manner.

It is always desirable to find improvements in doping techniques, and the present disclosure relates to such improvements.

### SUMMARY

The following presents a simplified summary of the disclosure in order to provide a basic understanding of some aspects of the disclosure. This summary is not an extensive overview of the disclosure. It is intended neither to identify key or critical elements of the disclosure nor to delineate the scope of the disclosure. Rather, its primary purpose is merely to present one or more concepts of the disclosure in a simplified form as a prelude to the more detailed description that is presented later.

The present disclosure relates to the placement of arsenic as an n-type dopant in a target area in order to form active regions in an NMOS semiconductor component. As discussed herein, the placement of arsenic as a dopant may encounter two problems: the channeling of arsenic to an undesired depth for dopant introduced via ion implantation, and the diffusion of arsenic past the boundaries of the active area during heat-induced annealing. It has been discovered that placing carbon in the target area (before, during, or after placing arsenic) may reduce the diffusion of arsenic out of the target area during annealing. Accordingly, the diffusion of arsenic may be suppressed by placing a carbon-containing arsenic diffusion suppressant in the target area prior to annealing. Data supporting this result is presented and discussed herein. The present disclosure suggests this technique for the formation of an n-type active area on a semiconductor substrate, and particularly for the formation of an NMOS transistor. Enhancements of this technique, as discussed herein, may further improve the process control over the depth of doping, the undesirable diffusion of arsenic, and maintenance of the regularity of the silicon lattice.

To the accomplishment of the foregoing and related ends, the following description and annexed drawings set forth in detail certain illustrative aspects and implementations of the disclosure. These are indicative of but a few of the various ways in which one or more aspects of the present disclosure may be employed. Other aspects, advantages and novel features of the disclosure will become apparent from the following detailed description of the disclosure when considered in conjunction with the annexed drawings.

### BRIEF DESCRIPTION OF THE DRAWINGS

FIG. 1 is a side elevation view in section illustrating a conventional dopant configuration.

FIGS. 2A-2B are a set of side elevation views in section that together illustrate a dopant configuration in accordance with the present disclosure.

FIGS. 3A-3B are another set of side elevation views in section that together illustrate a dopant configuration in accordance with the present disclosure.

FIGS. 4A-4B are charts illustrating some advantages of placement techniques in accordance with the present disclosure.

FIG. 5 is a flow diagram illustrating an exemplary method of placing a dopant in accordance with the present disclosure.

### DETAILED DESCRIPTION

One or more aspects of the present disclosure are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present disclosure. It may be evident, however, to one skilled in the art that one or more aspects of the present disclosure may be practiced with a lesser degree of these specific details. In other instances, well-known structures and devices are shown in block diagram form in order to facilitate describing one or more aspects of the present disclosure.

As discussed hereinabove, the present disclosure relates to the placement of arsenic in a target area of a semiconductor substrate for the purpose of forming an n-type active area. The control of the arsenic doping is facilitated by the introduction of a carbon-containing arsenic diffusion suppressant in the target area prior to annealing. Placing such an agent in the target area prior to annealing may reduce the diffusion of arsenic out of the target area, and may therefore enhance the border definition of the active area.

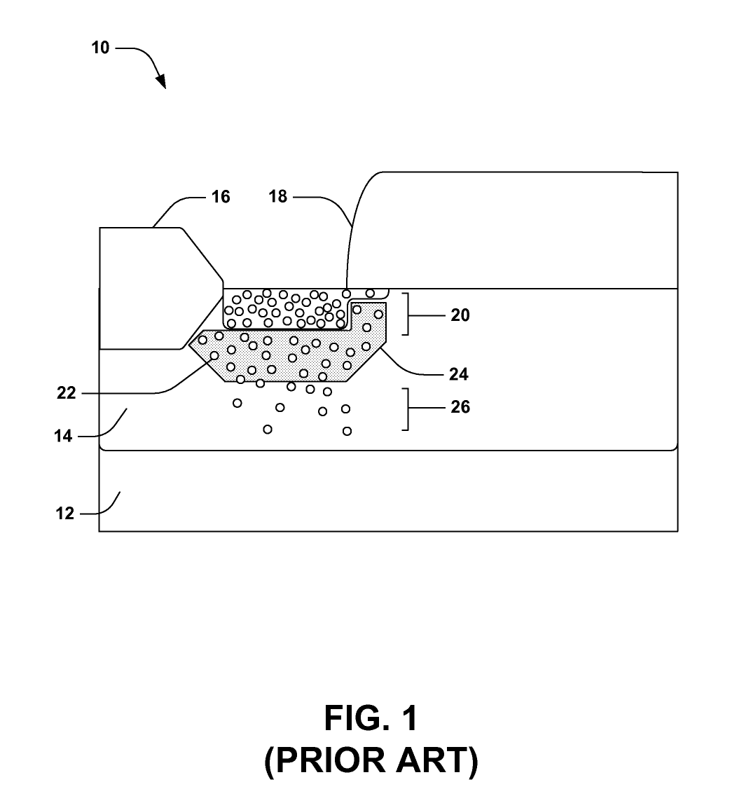

This advantage may be illustrated by reference to the figures of this disclosure. FIG. 1 represents a typical arsenic doping profile following annealing, and without the use of the enhanced techniques disclosed herein. In this figure, the NMOS semiconductor component 1 0 is illustrated comprising (in part) a silicon wafer 12 where an NMOS device, such as an NMOS transistor, is intended to be formed on the upper layer that will serve as the semiconductor substrate 14. The semiconductor substrate is often doped with the opposite type of dopant in order to provide electronic isolation of the components thereupon; however, other arrangements may also be suitable, such as when the substrate hosts an electronically active “pocket” region having the same electronic property but an increased dopant concentration. The electronically active region of the semiconductor substrate 14 may be isolated from other areas of the semiconductor by the use of an isolation structure 16, such as a localized oxidation of silicon (LOCOS) isolation structure or an isolation trench. This figure illustrates a portion of an NMOS transistor, where a gate 18 connects a target area 20 with another active area (not shown.) The target area 20 is intended to function as an active area of the transition, e.g., the source or drain region, and is rendered conductive by doping with arsenic 22. However, due to channeling and diffusion, the actual placement profile of arsenic 22 does not match the profile of the target area 20. The target area 20 contains a high concentration of arsenic dopant, but the arsenic 22 has also diffused out of the target region 20 both laterally and longitudinally into the surrounding area 24 of the semiconductor substrate 14. Additionally, the arsenic 22 has deeply penetrated the target area 20 to both a medium depth such as within the diffusion area 24, but also into a deeper area 26 of the semiconductor substrate 14. As used herein, the area 20 of the semiconductor 10 where arsenic 22 is intended to be placed will be described as the “target area”; the area 24 where diffusion occurs will be described as the “diffusion area”; and the area 26 where placement occurs at a relatively great depth due to channeling in an ion implantation placement will be describe as the “channeling area.” Due to the problems of channeling and diffusion during heat-induced annealing, the arsenic 22 has diffused out of the target area 20 into the diffusion area 24, and has also penetrated the semiconductor substrate 14 into the channeling area 26.

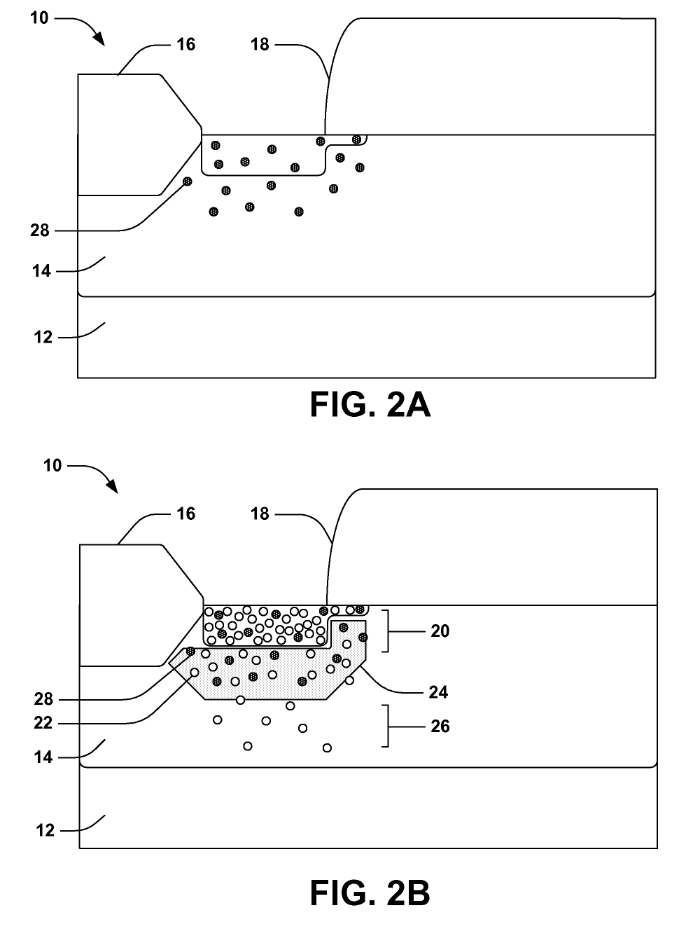

By contrast, FIGS. 2A-B illustrate an embodiment having a more desirable arsenic doping profile in accordance with the present disclosure. These figures again illustrate an NMOS semiconductor component 10 comprising (in part) a silicon wafer 12 having a semiconductor substrate 14, which may be isolated from neighboring electronically active areas via an isolation structure 16, and on which is to be formed a gate 18 bridging a target area 20 with another active area (not shown.) In this embodiment, the method of n-type doping a target area on a semiconductor substrate comprises placing a carbon-containing arsenic diffusion suppressant in the target area, and placing arsenic in the target area. FIG. 2A shows the introduction of a carbon-containing arsenic diffusion suppressant 28 that will cause the target area to retain more of the arsenic 22 and will reduce diffusion of the arsenic ions 22 into the diffusion area 24. A comparison between FIGS. 1 and 2B demonstrates that while arsenic may (or may not) still be present in the channeling area 26, the amount of arsenic that diffuses out of the target area 20, both laterally and longitudinally, into the diffusion area 24 is reduced. One embodiment of this method involves annealing the semiconductor substrate subsequent to doping with arsenic 22, e.g. by heat induction, in order to restore some of the lattice structure. The diffusion of arsenic during this heat-induced annealing will thereby be reduced.

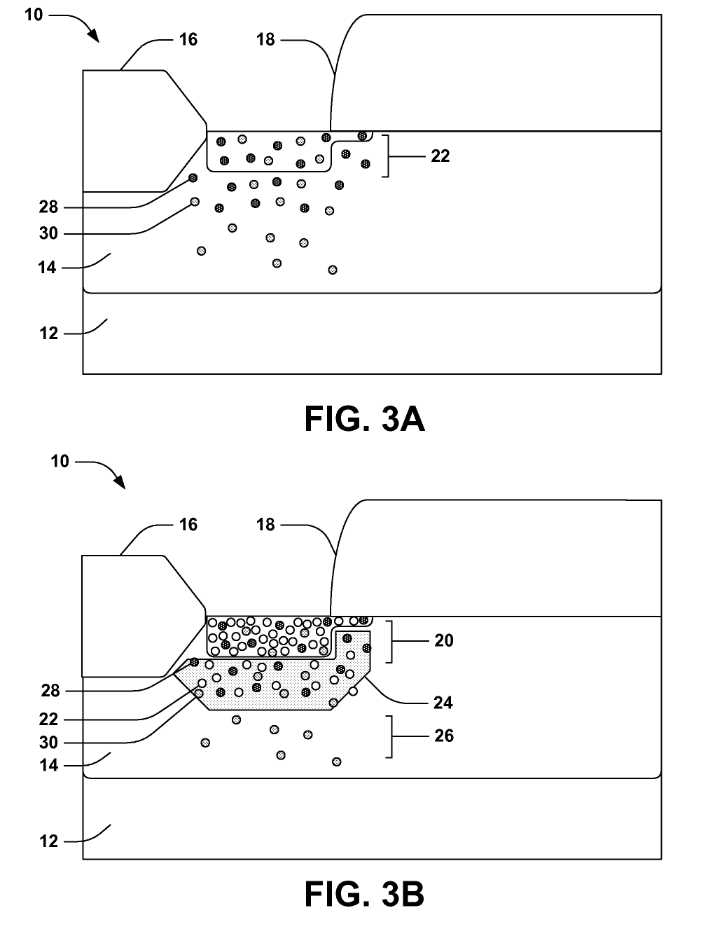

FIGS. 3A-B illustrate another embodiment in accordance with the present disclosure. These figures again illustrate an NMOS semiconductor component 10 comprising (in part) a silicon wafer 12 having a semiconductor substrate 14, which may be isolated from neighboring electronically active areas via an isolation structure 16, and on which is to be formed a gate 18 bridging a target area 20 with another active area (not shown.) As discussed above, deep doping may occur when an ion enters a longitudinal channel in the crystalline silicon lattice. The channeling and concomitant deep doping may be better controlled by amorphizing the lattice, which involves introducing some non-silicon atoms that disrupt the physical regularity of the lattice. The non-silicon atoms, known as an amorphizer, ideally comprise an electronically inert species that does not affect the functionality of the semiconductor components. One such species is germanium, which may be introduced, e.g. by ion implantation, in order to impart an amorphous structure without altering the electronic properties of the circuit. It will be appreciated that persons having ordinary skill in the art may be able to select a wide array of amorphizing agents that are compatible with the present disclosure, and to combine them with the concepts presented herein without undue experimentation. As shown in FIG. 3A, an amorphizer 30 may be introduced in addition to the carbon-containing arsenic diffusion suppressant 28 (which may be done before, during, or after the placement of the carbon-containing arsenic diffusion suppressant 22.) This amorphizer may be introduced by any suitable method, e.g., by ion implantation. When both an amorphizer 30 and a carbon-containing arsenic diffusion suppressant 28 are present, the placement of arsenic 22 and the subsequent anneal produce a doped region as illustrated in FIG. 3B, where the placement of arsenic 22 is more tightly controlled in both the diffusion area 24 (as a result of the carbon-containing arsenic diffusion suppressant 28) and in the channeling area 30 (as a result of the amorphizer.)

In another set of embodiments, the arsenic and carbon-containing arsenic diffusion suppressant are used in addition to another n-type dopant. As noted above, among the group IV elements, phosphorus is sometimes preferred over arsenic as an n-type dopant. This preference is motivated for the alleviation of some disadvantageous properties of arsenic as an n-type dopant. For instance, arsenic is a larger atom than phosphorus, so it causes more disruption to the crystalline lattice upon ion implantation. A heavy dose of arsenic implantation may disrupt the heavily doped area to such an extent that annealing cannot bring the lattice within process control tolerances. On the other hand, a pure phosphorus dopant may also be difficult to control, as the small size of phosphorus leads to greater rates of diffusion and channeling. Therefore, a blend of arsenic and phosphorus may be used (either together or in any appropriate order of placement.) In this set of embodiments, arsenic may be used in conjunction with an n-type dopant other than arsenic. In accordance with the present invention, the arsenic component of this mixed dopant is controlled with respect to diffusion by the introduction of a carbon-containing arsenic diffusion suppressant, and optionally with respect to channeling by the use of an amorphizer (e.g., germanium.)

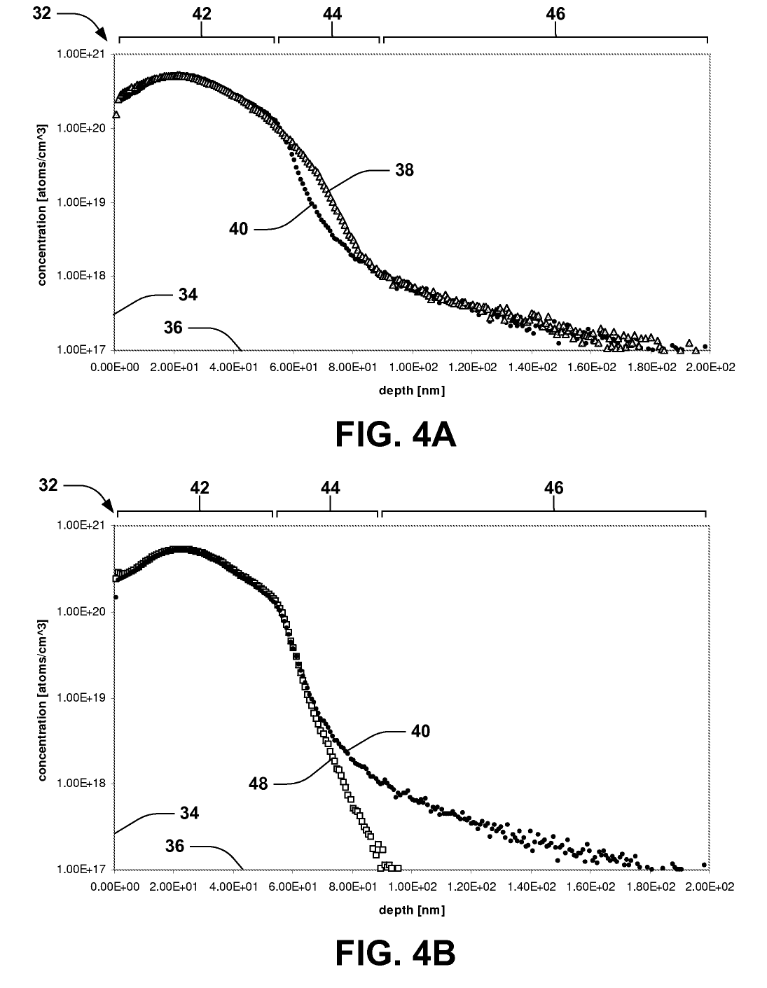

A demonstration of the properties described herein is provided in FIGS. 4A-B, which illustrate the depth of the arsenic placement profile in light of varying conditions. In FIG. 4A, the chart 32 features measurements of the concentration of dopant along the Y axis 34, and the depth of the target area along the X axis 36. In FIG. 4A, the profile for placement of arsenic 38 is contrasted with the profile for placement of arsenic in the presence of carbon 40. It will be apparent that the dopant concentration in the shallowest layer of the semiconductor substrate (the target area), corresponding to the vertical section of the chart labeled 42, is unchanged in the presence or absence of carbon. Similarly, the dopant concentration in the deepest layer of the semiconductor substrate (the channeling area), corresponding to the vertical section of the chart labeled 46, is also unchanged in the presence or absence of carbon. However, the dopant concentration in the middle layer of the semiconductor substrate (the diffusion area), corresponding to the vertical section of the chart labeled 44, indicates that the carbon operates as a carbon-containing arsenic diffusion suppressant, and reduces diffusion of the arsenic out of the target area.

The chart of FIG. 4B illustrates the further enhancement of using an amorphizer along with the carbon-containing arsenic diffusion suppressant. Again, the chart 32 features measurements of the concentration of dopant along the Y axis 34, and the depth of the target area along the X axis 36. In this figure, the profile for the placement of arsenic with carbon 40 is contrasted with the profile for the placement of arsenic in the presence of both carbon and an amorphizer 48. It will be apparent that the dopant concentration in the shallowest layer of the semiconductor substrate (the target area), corresponding to the vertical section of the chart labeled 42, is unchanged in the presence or absence of the amorphizer. Similarly, the dopant concentration in the middle layer of the semiconductor substrate (the diffusion area), corresponding to the vertical section of the chart labeled 44, is also unchanged in the presence or absence of the amorphizer. However, the dopant concentration in the deepest layer of the semiconductor substrate (the channeling area), corresponding to the vertical section of the chart labeled 46, the chart indicates that the amorphizer has disrupted the lattice of the semiconductor substrate sufficiently to reduce the number of channels, thereby reducing the penetration depth of the arsenic due to channeling.

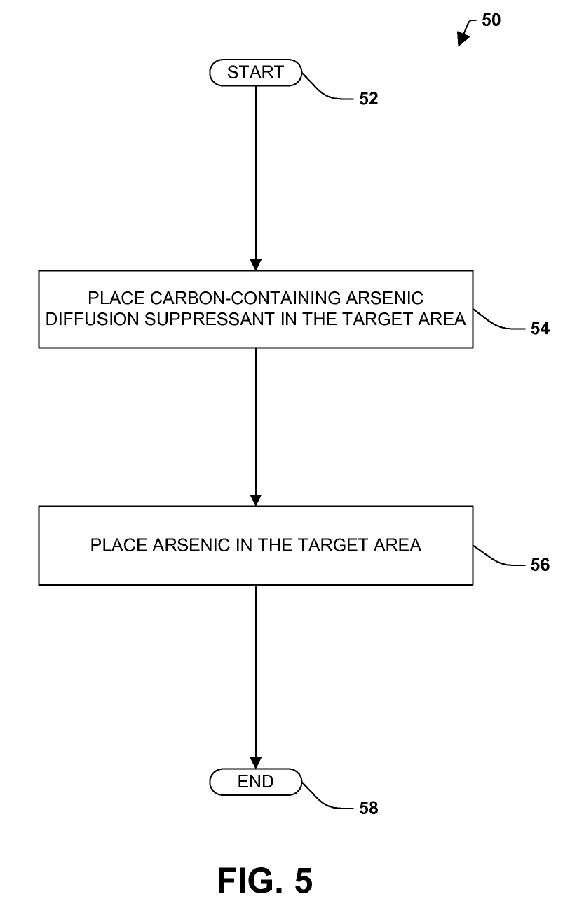

The method disclosed hereinabove describes the n-type doping of a target area in a semiconductor substrate. This method is illustrated in FIG. 5, in which the method 50 begins at 52 and involves the placement of a carbon-containing arsenic diffusion suppressant in the target area 54. The method also involves the placement of arsenic in the target area 56, after which the method ends at 58. The method 50 thereby produces an n-type doped area in a semiconductor substrate. As noted hereinabove, some embodiments may involve annealing the semiconductor substrate, e.g. by heat induction, to repair the disruptions of the silicon crystalline lattice. Some embodiments may involve the introduction (e.g., by ion implantation) of an amorphizer (e.g., germanium) prior to the placement of arsenic. Some embodiments may involve the introduction of a blend of arsenic with an n-type dopant other than phosphorus, such as another type IV element (e.g., phosphorus.) Other variations are also possible. All such methods, and the products of these various methods, are included in the scope of this disclosure.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (assemblies, elements, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, “exemplary” as utilized herein merely means an example, rather than the best.

What is claimed is:

1. A method of n-type doping a target area on a semiconductor substrate, the method comprising:
placing a carbon-containing arsenic diffusion suppressant in the target area; and
placing arsenic in the target area.

2. The method of claim 1, further comprising:
subsequent to placing arsenic, annealing the semiconductor substrate.

3. The method of claim 1, where the carbon-containing arsenic diffusion suppressant primarily comprises carbon.

4. The method of claim 1, further comprising:
prior to placing arsenic, amorphizing the target area.

5. The method of claim 4, where the amorphizing comprises placing an amorphizer in the target area.

6. The method of claim 5, where the amorphizer comprises germanium.

7. The method of claim 1, further comprising:
placing an n-type dopant other than arsenic in the target area.

8. A method of forming a semiconductor component having at least two electronically active target area on a semiconductor substrate, the method comprising:
placing a carbon-containing arsenic diffusion suppressant in at least one of the target areas;
placing arsenic in the target areas; and
forming a gate that connects the target areas.

9. The method of claim 8, further comprising:
subsequent to placing arsenic, annealing the semiconductor substrate.

10. The method of claim 8, where the carbon-containing arsenic diffusion suppressant primarily comprises carbon.

11. The method of claim 8, further comprising:
prior to placing arsenic, amorphizing at least one of the target areas.

12. The method of claim 11, where the amorphizing comprises placing an amorphizer in the target area.

13. The method of claim 12, where the amorphizer comprises germanium.

14. The method of claim 8, further comprising:
placing an n-type dopant other than arsenic in at least one of the target areas.

15. A semiconductor component formed on a semiconductor substrate, where the semiconductor component is formed by the method of claim 8.

16. A semiconductor component having at least one n-type doped target area and formed on a semiconductor substrate, where the n-type doped target area is formed by:
placing a carbon-containing arsenic diffusion suppressant in the target area; and
placing arsenic in the target area.

17. The component of claim 16, further comprising:
subsequent to placing arsenic, annealing the semiconductor substrate.

18. The component of claim 16, where the carbon-containing arsenic diffusion suppressant primarily comprises carbon.

19. The component of claim 16, further comprising:
prior to placing arsenic, amorphizing at least one of the target areas.

20. The component of claim 19, where the amorphizing comprises placing an amorphizer.

21. The component of claim 20, where the amorphizer comprises germanium.

22. The component of claim 16, further comprising:
placing an n-type dopant other than arsenic in at least one of the target areas.
